(19) United States
(12) Patent Application Publication
(10) Pub. No.: US 2026/0101732 A1
(43) Pub. Date: Apr. 9, 2026

(54) METHODS OF DEPOSITING IRIDIUM-CONTAINING FILMS FOR MICROELECTRONIC DEVICES

(71) Applicant: Applied Materials, Inc., Santa Clara, CA (US)

(72) Inventors: Chandan Das, Singapore (SG); Feng Q. Liu, San Jose, CA (US); Zhiyuan Wu, San Jose, CA (US); Jiecong Tang, Singapore (SG); John Sudijono, Singapore (SG); Mark Saly, Santa Clara, CA (US)

(73) Assignee: Applied Materials, Inc., Santa Clara, CA (US)

(21) Appl. No.: 18/906,342

(22) Filed: Oct. 4, 2024

(51) Int. Cl. H01L 21/768

(52) U.S. Cl. CPC H10W 20/038; H10W 20/035; H10W 20/057

(57) ABSTRACT

Methods of manufacturing interconnect structures as part of a microelectronic device fabrication process are described. Methods of selectively depositing iridium-containing films are also described. The methods include exposing a substrate including a metallic material and a dielectric material to an iridium-containing precursor and a reactant to form the iridium-containing film. The iridium-containing film selectively grows on the metallic material relative to the dielectric material.

### TECHNICAL FIELD

Embodiments of the disclosure generally relate to methods of depositing iridium-containing films. In particular, embodiments of the disclosure are directed to methods of selectively depositing iridium-containing films in back-end of line (BEOL) processes.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies and processes have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle includes exposing the substrate surface to a first precursor, a purge gas, a second precursor, and the purge gas. The first and second precursors react to form a product compound as a layer on the substrate surface. The cycle is repeated to form the layer to a desired thickness.

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both metal lines and metal vias and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increase power consumption.

A conventional interconnect structure, such as a copper interconnect structure, for example, includes a barrier layer deposited on the sidewalls of a via, the sidewalls made of a dielectric material, providing good adhesion and preventing conductive metal, such as copper, from diffusing into the dielectric material. Barrier layers can typically be the largest contributor to via resistance due to high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

The advancing complexity of advanced microelectronic devices is placing stringent demands on currently used deposition techniques. Unfortunately, there are a limited number of viable precursors to provide films with suitable crystallinity, grain size, continuity, and electrical conductivity for microelectronic device fabrication processes. In addition, precursors that often meet these properties still suffer from poor long-term stability and lead to thin films that contain elevated concentrations of contaminants such as oxygen, nitrogen, and/or halides that are often deleterious to the target film application.

Accordingly, there is a need for methods for depositing material layers that improve performance of interconnects, for example, reducing via resistance and improving deposition selectivity.

### SUMMARY

One or more embodiments of the disclosure are directed to a method of selectively depositing an iridium-containing film. In some embodiments, the method comprises exposing a substrate including a metallic material and a dielectric material to an iridium-containing precursor and a reactant to form the iridium-containing film, wherein the iridium-containing film selectively grows on the metallic material relative to the dielectric material.

Additional embodiments of the disclosure are directed to a method of manufacturing an interconnect structure. In some embodiments, the method comprises forming a dielectric layer on a substrate, the dielectric layer including at least one feature defining a gap having sidewalls comprising a dielectric material and a bottom comprising a metallic material; selectively depositing a barrier layer on the sidewalls; depositing a metal liner on the barrier layer; filling the gap with a gapfill material comprising one or more of copper (Cu), manganese (Mn), tungsten (W), ruthenium (Ru), or molybdenum (Mo); and selectively depositing an iridium-containing film on the gapfill material relative to the dielectric material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional schematic view of a substrate in accordance with one or more embodiments of the disclosure;

FIG. 1B illustrates a cross-sectional schematic view of a substrate in accordance with one or more embodiments of the disclosure;

FIG. 2 illustrates a process flow diagram of a method of manufacturing an interconnect structure in accordance with one or more embodiments of the disclosure;

FIG. 3A illustrates a cross-sectional schematic view of a bottom interconnect structure formed on a substrate, an etch stop layer formed on the bottom interconnect structure, and a dielectric layer on formed on the etch stop layer, the dielectric layer including at least one feature defining a gap having sidewalls and a bottom, in accordance with one or more embodiments of the disclosure;

FIG. 3B illustrates a cross-sectional schematic view of a barrier layer deposited on the at least one feature of FIG. 3A and a metal liner deposited on the barrier layer, in accordance with one or more embodiments of the disclosure;

FIG. 3C illustrates a cross-sectional schematic view of filling the gap of FIG. 3B with a gapfill material to form a top interconnect structure, in accordance with one or more embodiments of the disclosure; and

FIG. 3D illustrates a cross-sectional schematic view of an iridium-containing film selectively deposited on the gapfill material relative to the dielectric layer, in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular aspects, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed therein/thereon.

A “substrate” as used herein, refers to any substrate or material surface formed on a substrate upon which film processing is performed during a fabrication process. For example, a substrate surface on which processing can be performed include dielectric materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

As used herein, “selective” deposition of materials can be accomplished in a variety of ways. For instance, some processes may have inherent selectivity to surfaces based on their surface chemistry. These processes are rare, and are typically specific to the reactants used, materials formed, and the substrate surfaces. A chemical precursor may react selectively with one surface relative to another surface (e.g., metallic vs. dielectric, or vice versa). Process parameters such as pressure, substrate temperature, precursor partial pressures, and/or gas flows may be modulated to tune the chemical kinetics of a particular surface reaction.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate. In semiconductor device (inclusive microelectronic device) fabrication, the sputtering process is usually accomplished within a PVD processing chamber or a sputtering chamber. Sputtering has long been used for the deposition of metals and related materials in the fabrication of integrated circuits.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, unreacted reactant, reaction products and by-products from the region in which the substrate is processed, i.e., the processing region. The purge process can include moving the substrate through a gas curtain to a portion or sector of the processing region that contains none or substantially none of the precursor or reactant, respectively. In one or more embodiments, purging the processing region comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone (e.g., the processing region) of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second time delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B, and purge gas defines a cycle. A cycle can start with either compound A or compound B and continue the respective order of the cycle until a layer with the predetermined thickness is formed.

As used herein, the term “thermal” refers to a process that does not involve the use of plasma. As used herein, the term “plasma” refers to a composition have ionically charged species and uncharged neutral and radical species. As used herein, a “radical-rich plasma” comprises greater than 50% radical species.

As used herein, as will be understood by the skilled artisan, a layer/film which is “conformal” or “conformally deposited” refers to a layer/film where the thickness is about the same throughout. A layer/film which is conformal varies in thickness by less than or equal to about 5%, 2%, 1% or 0.5%.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

Embodiments of the present disclosure provide methods of manufacturing interconnect structures in a microelectronic device fabrication process. Some embodiments of the disclosure provide methods for improving performance of interconnects.

Interconnects comprise metal lines that transfer current within the same device layer, and metal vias that transfer current between layers. These metal lines and metal vias are formed with conductive metals such as one or more of copper (Cu), manganese (Mn), tungsten (W), ruthenium (Ru), or molybdenum (Mo) in “gap(s)” formed within a microelectronic device.

In one or more embodiments, a dielectric layer comprises at least one feature defining the “gap” and the gap includes sidewalls and a bottom. In one or more embodiments, the sidewalls comprise a dielectric material and the bottom comprises a metallic material.

In one or more embodiments, the gap comprises metal lines that transfer current within the same device layer and metal vias that transfer current between layers. In one or more embodiments, each of the metal lines have a sidewall and a bottom. In one or more embodiments, each of the metal vias have a sidewall and a bottom. As used herein, unless specified otherwise, reference to the “bottom of the gap” is intended to mean the bottom of the metal via, which is nearest the substrate.

In one or more embodiments, the microelectronic devices described herein comprise at least one top interconnect structure that is interconnected to at least one bottom interconnect structure.

Embodiments of the present disclosure provide microelectronic devices and methods of manufacturing microelectronic devices that improve performance of interconnects, for example, reducing via resistance. Embodiments of the disclosure provide methods of depositing iridium-containing films that have desired crystallinity, grain size, continuity, and electrical conductivity properties in the miniaturization and scaling of integrated circuits.

Iridium is a proposed material for integration owing to its high melting point (ability to withstand high current densities), exceptional density, and ability to conduct electrical current. Iridium and iridium-containing films have attractive material and conductive properties.

The iridium-containing films according to one or more embodiments can advantageously be used in memory and logic applications. Embodiments of the disclosure are directed to methods of selectively depositing iridium-containing films in back-end of line (BEOL) processes.

Some embodiments are directed to a method of selectively depositing an iridium-containing film. Some embodiments are directed to a method of manufacturing an interconnect structure as part of a microelectronic device fabrication process. Some embodiments are directed to methods of selectively depositing an iridium-containing film for self-aligned capping applications. Some embodiments are directed to methods of selectively depositing an iridium-containing film that is used as a capping layer for an interconnect structure as part of a microelectronic device fabrication process.

Current processes typically employ cobalt (Co) for copper (Cu) capping applications, which, unfortunately, have reliability issues. It has been found that the slow migration of capping metals such as cobalt (Co) to the barrier layer (e.g., tantalum nitride (TaN)) lead to potential capping layer decay which can lead to electromigration issues. Advantageously, embodiments of the present disclosure are directed to selectively depositing iridium-containing films for copper (Cu) capping applications. It has been advantageously found that the selectively deposited iridium-containing films described herein have better adhesion to conductive materials, such as copper (Cu), as compared to cobalt (Co). Advantageously, selectively depositing the iridium-containing film in accordance with one or more embodiments is an inherently selective process. Additionally, the inherently selective deposition process described herein can reduce the amount of extra deposition steps during integration (such as, for example, use of blocking layer on dielectrics and removal).

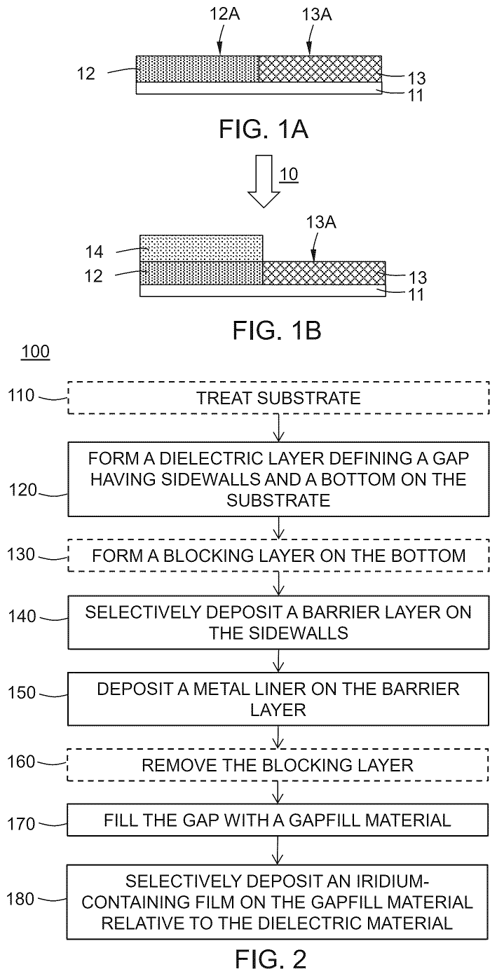

Methods of selectively depositing iridium-containing films are described with reference to FIGS. 1A-1B. FIGS. 1A-1B illustrate cross-sectional schematic views of a substrate 11 including a first material 12 comprising a first surface 12A and a second material 13 comprising a second surface 12B. In some embodiments, the first material 12 is a metallic material. The first material 12 can include any suitable metallic material. In some embodiments, the metallic material comprises one or more of copper (Cu), manganese (Mn), tungsten (W), ruthenium (Ru), or molybdenum (Mo). In some embodiments, the second material 13 is a dielectric material. The second material 13 can include any suitable dielectric material. In some embodiments, the dielectric material comprises one or more of an oxide, silicon oxycarbide (SiOC), silicon oxycarbonitride (SiOCN), a low-κ dielectric material, or a high-κ dielectric material. In accordance with operation 10, an iridium-containing film 14 is selectively formed on the first surface 12A relative to the second surface 13A. Advantageously, operation 10 illustrates an inherently selective process.

The substrate 11 including the first material 12 and the second material 13 is exposed to an iridium-containing precursor and a reactant to form the iridium-containing film 14. The iridium-containing precursor can be any precursor that includes iridium (Ir). In some embodiments, the iridium-containing precursor comprises one or more of Ir(acac)₃, Ir(CpMe)(COD), Ir(CpEt)(COD), or Ir(CO)₃(tBusCyp). The reactant can be any suitable reactant that reacts with the iridium-containing precursor to form the iridium-containing film 14. In some embodiments, the reactant comprises one or more of hydrogen (H₂), ammonia (NH₃), nitrogen (N₂), argon (Ar), or helium (He).

In some embodiments, the substrate 11 is exposed to the iridium-containing precursor and the reactant simultaneously. In some embodiments, the substrate 11 is exposed to the iridium-containing precursor and the reactant sequentially. In some embodiments, the reactant is pulsed continuously, and the iridium-containing precursor is pulsed intermittently.

In one or more embodiments where the reactant is pulsed continuously, and the iridium-containing precursor is pulsed intermittently, the iridium-containing precursor is pulsed for a time period in a range of from 0.1 seconds to 10 seconds. In one or more embodiments where the reactant is pulsed continuously, and the iridium-containing precursor is pulsed intermittently, there is a time delay after each pulse of the iridium-containing precursor. In one or more embodiments where the reactant is pulsed continuously, and the iridium-containing precursor is pulsed intermittently, the time delay is in a range of from 0.1 seconds to 20 seconds. In one or more embodiments where the reactant is pulsed continuously, and the iridium-containing precursor is pulsed intermittently, the time delay is 15 seconds.

In one or more embodiments where the reactant is pulsed continuously, and the iridium-containing precursor is pulsed intermittently, the iridium-containing precursor is pulsed for a time period in a range of from 0.1 seconds to 10 seconds, followed by a time delay of 15 seconds where the reactant is pulsed continuously to define a process sequence. This process sequence can be repeated any suitable number of times to deposit the iridium-containing film 14 to a predetermined thickness.

The selective deposition process of operation 10 can be performed at any suitable processing conditions. In some embodiments, the selective deposition process of operation 10 is performed at a temperature in a range of from 20° C. to 550° C. In some embodiments, the selective deposition process of operation 10 comprises a thermal atomic layer deposition (ALD) process performed at a temperature in the range of from 20° C. to 450° C. In some embodiments, the selective deposition process of operation 10 is performed at a pressure in a range of from 100 mTorr to 760 Torr.

In accordance with one or more embodiments, at operation 10, the iridium-containing film 14 selectively grows on the first surface 12A relative to the second surface 13A.

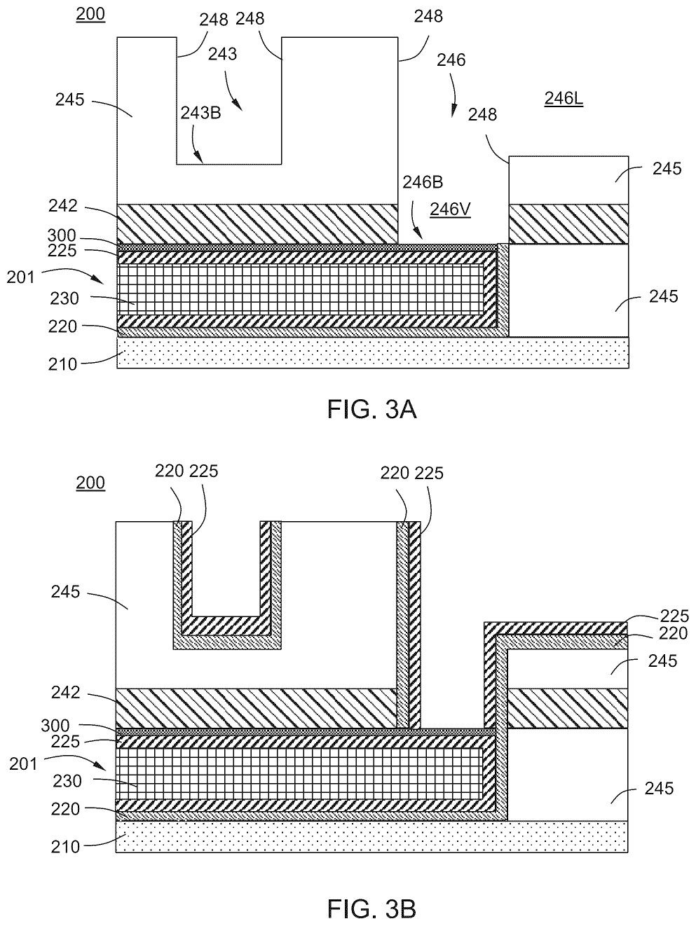

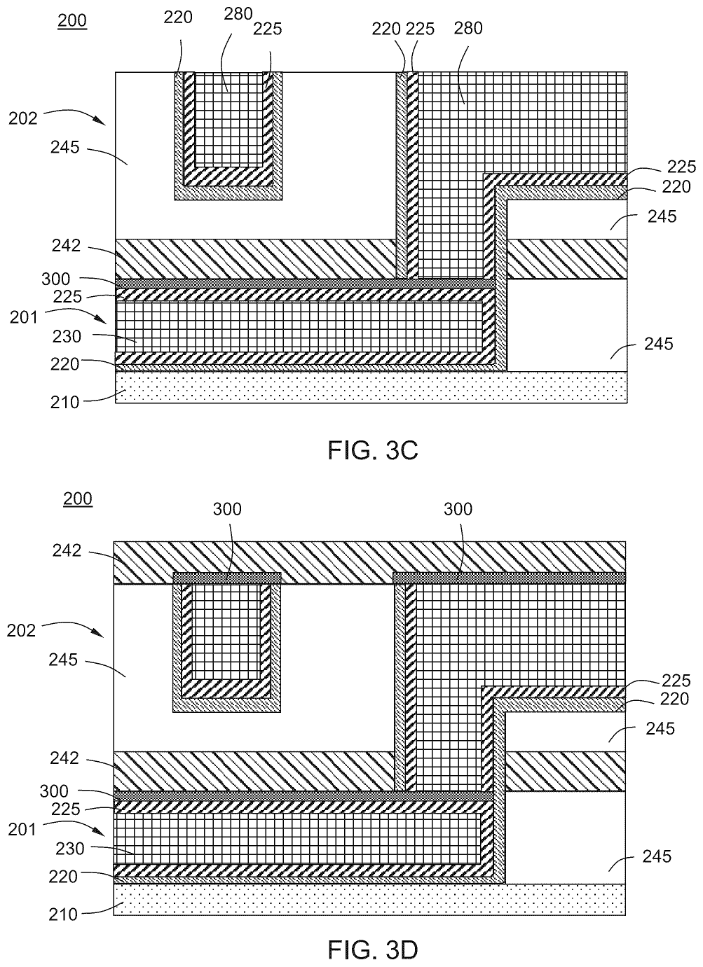

Methods of manufacturing an interconnect structure as part of a microelectronic device fabrication process are described with reference to FIGS. 2 and 3A-3D. FIG. 2 is a process flow diagram of a method 100 of manufacturing an interconnect structure that is part of a microelectronic device 200. FIGS. 3A-3D illustrate stages of manufacture of the interconnect structure that is part of the microelectronic device 200 during the method 100.

It will be appreciated by the skilled artisan that one or more additional operations needed to complete the fabrication of a microelectronic device are known to the skilled artisan and are within the scope of the present disclosure without undue experimentation.

The method 100 comprises, consists essentially of, or consists of: optionally treating a substrate 210 (operation 110); forming a dielectric layer 245 on the substrate 210 (operation 120), the dielectric layer 245 including at least one feature, e.g. a first feature 243 defining a gap having sidewalls 248 and a bottom 243B, and a second feature 246 defining a gap having sidewalls 248 and a bottom 246B; optionally forming a blocking layer (not shown) on the bottom 246B (operation 130); selectively depositing a barrier layer 220 on the sidewalls 248 (operation 140); depositing a metal liner 225 on the barrier layer 220 (operation 150); optionally removing the blocking layer (operation 160); filling the gap with a gapfill material 280 comprising one or more of copper (Cu), manganese (Mn), tungsten (W), ruthenium (Ru), or molybdenum (Mo) (operation 170); and selectively depositing an iridium-containing film on the gapfill material 280 relative to the dielectric material (operation 180).

Referring to FIGS. 3A-3D, a portion of a microelectronic device 200 is shown during stages of manufacture. In FIG. 3A, the microelectronic device 200 comprises the substrate 210, a barrier layer 220 on the substrate 210, a metal liner 225 on the barrier layer 220, a metal layer 230 on the metal liner 225, an iridium-containing film 300 (described in further detail herein) on the metal layer 230 (which can include the iridium-containing film 300 on the metal layer 230 and the metal liner 225), an etch stop layer 242 on the iridium-containing film 300, and the dielectric layer 245 on the etch stop layer 242.

It will be appreciated that in one or more embodiments, the metal layer 230 forms a metal line that transfers current within the same device layer. It will also be appreciated that the barrier layer 220 on the substrate 210, the metal liner 225 on the barrier layer 220, and the metal layer 230 on the metal liner 225 define a bottom interconnect structure 201, and the bottom interconnect structure 201 includes the iridium-containing film 300 formed on the metal layer 230 (which can include the iridium-containing film 300 on the metal layer 230 and the metal liner 225).

In one or more embodiments, the substrate 210 is a wafer. In one or more embodiments, the substrate 210 is an etch stop layer on a wafer. In one or more embodiments, the substrate 210 is an aluminum oxide etch stop layer on a wafer.

The barrier layer 220 can include any suitable material that is configured to prevent conductive metal, such as, for example, one or more of copper (Cu), manganese (Mn), tungsten (W), ruthenium (Ru), or molybdenum (Mo), from diffusing into the dielectric layer 245. In one or more embodiments, the barrier layer 220 on the substrate 210 comprises tantalum nitride (TaN). In one or more embodiments, the barrier layer 220 on the substrate 210 comprises tantalum nitride (TaN) formed by ALD. The barrier layer 220 can have any suitable thickness. In one or more embodiments, the barrier layer 220 has a thickness in a range of from about 2 Å to about 10 Å.

The metal liner 225 comprises one or more of copper (Cu), manganese (Mn), tungsten (W), ruthenium (Ru), or molybdenum (Mo). The metal liner 225 can be deposited by any suitable deposition technique. In one or more embodiments, the metal liner 225 is formed by ALD. The metal liner 225 can have any suitable thickness. In one or more embodiments, the metal liner 225 has a thickness in a range of from about 10 Å to about 40 Å. In one or more embodiments, a portion of the metal liner 225 is etched.

The metal layer 230 comprises one or more of copper (Cu), manganese (Mn), tungsten (W), ruthenium (Ru), or molybdenum (Mo). In one or more embodiments, the metal layer 230 comprises one or more of copper (Cu), molybdenum (Mo), or tungsten (W). In one or more embodiments, a portion of the metal layer 230 is etched.

In one or more embodiments, as will be described further herein, the metal layer 230, the metal liner 225, or both of the metal liner 225 and the metal layer 230 collectively, includes a capping layer (i.e., the iridium-containing film 300) formed directly thereon. In one or more embodiments, the etch stop layer 242 comprises one or more of aluminum oxide, silicon nitride, or aluminum nitride.

In some embodiments, the dielectric layer 245 comprises a dielectric material. In some embodiments, the dielectric material comprises one or more of an oxide, silicon oxycarbide (SiOC), silicon oxycarbonitride (SiOCN), a low-κ dielectric material, or a high-κ dielectric material.

The dielectric layer 245 on top of the etch stop layer 242 comprises at least one feature, e.g. the first feature 243 defining a gap having sidewalls 248 and a bottom 243B, and the second feature 246 defining a gap having sidewalls 248 and a bottom 246B. FIGS. 3A-3D illustrate the substrate 210 having two features (i.e., the first feature 243 and the second feature 246) for illustrative purposes; however, those skilled in the art will understand that there can be more than two features or fewer than two features.

In some embodiments, the at least one feature defines a cylindrical via that, when filled with metal, transfers current between layers, and lines that transfer current within the same device layer. In some embodiments, the second feature 246 defines a via portion 246V and a line portion 246L.

In one or more embodiments, the bottom 243B of the gap of the first feature 243 is defined by the dielectric layer 245 and as such, comprises a dielectric material. In one or more embodiments, the bottom 246B of the gap of the second feature 246 is defined by the metal liner 225. In one or more embodiments, the bottom 246B of the gap of the second feature 246 is defined by the iridium-containing film 300 formed directly on the metal liner 225. In one or more embodiments, the bottom 246B of the gap of the second feature 246 comprises a mixture of iridium (Ir) from the iridium-containing film 300 and one or more of copper (Cu), manganese (Mn), tungsten (W), ruthenium (Ru), or molybdenum (Mo) from the metal liner 225.

In one or more embodiments, beginning at FIG. 3B, the method 100 is performed to form a top interconnect structure 202 (shown as completed in FIG. 3D) on the etch stop layer 242 on the bottom interconnect structure 201.

The method 100 optionally includes, at operation 110, treating the substrate 210. The substrate 210 can be treated in accordance with operation 110 before or after the bottom interconnect structure 201 is formed. In one or more embodiments, keeping the treatment process of operation 110 under vacuum ensures that no oxide is introduced/formed on the substrate 210 during the method 100. At operation 110, treating the substrate 210 removes native oxides from the surface of the substrate 210.

Treating the substrate 210 at operation 110 can include any suitable process. In some embodiments, treating the substrate 210 comprises exposing the substrate 210 to thermal H₂, thermal H₂/Ar, or thermal H₂/N₂. In some embodiments, treating the substrate 210 comprises exposing the substrate 210 to a plasma of H₂/Ar, a plasma of H₂, a plasma of NH₃, or a plasma of H₂/NH₃. Treating the substrate 210 at operation 110 can be performed for any suitable duration of time. In some embodiments, treating the substrate 210 occurs for a time period in a range of from 1 second to 300 seconds. As used herein, the term “substrate 210” can be used to refer to a substrate and/or a treated substrate, unless the context clearly indicates otherwise.

Referring to FIGS. 2 and 3A, at operation 120, the method 100 comprises forming the dielectric layer 245 on the substrate 210, e.g., the treated substrate. The dielectric layer 245 comprises at least one feature, e.g. the first feature 243 defining the gap having sidewalls 248 and the bottom 243B, and the second feature 246 defining the gap having sidewalls 248 and the bottom 246B.

In one or more unillustrated embodiments, at operation 130, the method 100 optionally includes forming a blocking layer on the bottom 246B by exposing the substrate 210 to a blocking compound.

In one or more embodiments, the blocking layer is formed on the bottom 246B of the gap in accordance with operation 130 of the method 100. Stated differently, in one or more embodiments, the blocking layer is formed on the iridium-containing film 300 on the metal layer 230, the metal liner 225, or both of the metal liner 225 and the metal layer 230 collectively, which defines the bottom 246B of the gap. In one or more embodiments, the blocking layer is formed selectively on the bottom 246B of the gap by exposing the substrate 210 to a blocking compound.

Embodiments of the present disclosure employ blocking compounds that can be used to form a blocking layer on a surface to suppress or prevent subsequent deposition on that surface. Any blocking compound that suppresses or prevents subsequent deposition on a metallic surface, e.g., the iridium-containing film 300 on the metal layer 230, the metal liner 225, or both of the metal liner 225 and the metal layer 230 collectively, which defines the bottom 246B of the gap, may be used.

In some embodiments, the processing conditions for exposing the substrate 210 to the blocking compound to form the blocking layer may be controlled and may be varied depending on the composition of the blocking compound.

Referring to FIGS. 2 and 3B, at operation 140 of the method 100, the barrier layer 220 is deposited directly on the dielectric layer 245. In the first feature 243, the barrier layer 220 is deposited conformally along the sidewalls 248 and the bottom 243B. In the second feature 246, the barrier layer 220 is selectively deposited on the sidewalls 248. In one or more embodiments, the barrier layer 220 does not form on the bottom 246B due to the presence of the blocking layer. Due to the presence of the blocking layer, in one or more embodiments, the barrier layer 220 selectively forms on the sidewalls 248 and extends towards the bottom 246B without forming on the bottom 246B.

In one or more embodiments, when the blocking layer is not present, the deposition of the barrier layer 220 in the second feature 246 is conformal, such that the barrier layer 220 forms on the sidewalls 248 and on the bottom 246B.

The barrier layer 220 may be deposited using any suitable deposition technique. The barrier layer 220 on the at least one feature, e.g., the first feature 243 and the second feature 246, can be the same as the barrier layer 220 formed directly on the substrate 210. In one or more embodiments, the barrier layer 220 on the at least one feature, e.g., the first feature 243 and the second feature 246, comprises tantalum nitride (TaN). In one or more embodiments, the barrier layer 220 on the at least one feature, e.g., the first feature 243 and the second feature 246, comprises tantalum nitride (TaN) formed by ALD.

Advantageously, the barrier layer 220 is configured to prevent conductive metal, such as, for example, one or more of copper (Cu), manganese (Mn), tungsten (W), ruthenium (Ru), or molybdenum (Mo), from diffusing into the dielectric layer 245.

Referring still to FIGS. 2 and 3B, at operation 150 of the method 100, the metal liner 225 is deposited directly on the barrier layer 220. In the first feature 243, the metal liner 225 is conformally deposited on the barrier layer 220. In the second feature 246, the metal liner 225 is selectively deposited on the barrier layer 220 formed on the sidewalls 248. In one or more embodiments, the metal liner 225 does not form on the bottom 246B due to the presence of the blocking layer. Due to the presence of the blocking layer, in one or more embodiments, the metal liner 225 selectively forms on the barrier layer 220 on the sidewalls 248 and extends towards the bottom 246B without forming on the bottom 246B.

In one or more embodiments, when the blocking layer is not present, the deposition of the barrier layer 220 in the second feature 246 is conformal, such that the barrier layer 220 forms on the sidewalls 248 and on the bottom 246B, and the metal liner 225 is conformally deposited on the barrier layer 220.

The metal liner 225 comprises one or more of copper (Cu), manganese (Mn), tungsten (W), ruthenium (Ru), or molybdenum (Mo). The metal liner 225 can be deposited by any suitable deposition technique. In one or more embodiments, the metal liner 225 is formed by ALD. The metal liner 225 can have any suitable thickness. In one or more embodiments, the metal liner 225 has a thickness in a range of from about 10 Å to about 40 Å.

At operation 160, the method 100 optionally includes removing the blocking layer, if a blocking layer is employed. In one or more embodiments, removing the blocking layer comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the barrier layer 220 and/or the metal liner 225.

Referring to FIGS. 2 and 3C, at operation 170, the method 100 comprises filling the gap(s), e.g., the gap of the first feature 243 and the gap of the second feature 246, respectively, with a gapfill material 280. In one or more embodiments, filling the gap(s) with the gapfill material 280 comprises a gap fill process.

The gap fill process can include any suitable deposition technique. In one or more embodiments, the gap fill process comprises a physical vapor deposition (PVD) process.

The gapfill material 280 may include any suitable material, such as a conductive material. In one or more embodiments, the gapfill material 280 comprises one or more of copper (Cu), manganese (Mn), tungsten (W), ruthenium (Ru), or molybdenum (Mo). In one or more embodiments, the gap fill process comprises filling the gap(s), e.g., the gap of the first feature 243 and the gap of the second feature 246, respectively, with one or more of copper (Cu), manganese (Mn), tungsten (W), ruthenium (Ru), or molybdenum (Mo) by physical vapor deposition (PVD). In one or more embodiments, the gap fill process comprises filling the gap(s), e.g., the gap of the first feature 243 and the gap of the second feature 246, respectively, with one or more of copper (Cu), tungsten (W), or molybdenum (Mo) by physical vapor deposition (PVD).

The gapfill material 280 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gapfill material 280 an atomic basis, comprises seams and/or voids. Advantageously, in one or more embodiments, the gapfill material 280 is free of seams and/or voids.

In one or more embodiments, after filling the gap(s), e.g., the gap of the first feature 243 and the gap of the second feature 246, respectively, with the gapfill material 280, a completed interconnect structure, e.g., the top interconnect structure 202 is formed, such that additional interconnect structures may be formed on top of the top interconnect structure 202.

Referring to FIGS. 2 and 3D, at operation 180, the method 100 comprises selectively depositing an iridium-containing film 300 on the gapfill material 280 of the first feature 243 and the gapfill material 280 of the second feature 246 relative to the dielectric layer 245. In one or more embodiments, the iridium-containing film 300 is selectively deposited on the gapfill material 280 of the first feature 243 and the gapfill material 280 of the second feature 246, and on the metal liner 225 in the top interconnect structure 202 relative to the dielectric layer 245. In one or more embodiments, the iridium-containing film 300 forms on the barrier layer 220 in the in the top interconnect structure 202. Advantageously, selectively depositing the iridium-containing film 300 on the gapfill material 280 of the first feature 243 and the gapfill material 280 of the second feature 246, on the metal liner 225 in the top interconnect structure 202, and/or on the barrier layer 220 in the top interconnect structure 202 relative to the dielectric layer 245 is an inherently selective process.

The substrate 210 is exposed to an iridium-containing precursor and a reactant to form the iridium-containing film 300. The iridium-containing precursor can be any precursor that includes iridium (Ir). In some embodiments, the iridium-containing precursor comprises one or more of Ir(acac)₃, Ir(CpMe)(COD), Ir(CpEt)(COD), or Ir(CO)₃(tBu₃Cyp). The reactant can be any suitable reactant that reacts with the iridium-containing precursor to form the iridium-containing film 300. In some embodiments, the reactant comprises one or more of hydrogen (H₂), ammonia (NH₃), nitrogen (N₂), argon (Ar), or helium (He).

In some embodiments, the substrate 210 is exposed to the iridium-containing precursor and the reactant simultaneously. In some embodiments, the substrate 210 is exposed to the iridium-containing precursor and the reactant sequentially. In some embodiments, the reactant is pulsed continuously, and the iridium-containing precursor is pulsed intermittently.

Each of the configurations of selectively depositing the iridium-containing film 300, e.g., where the substrate 210 is exposed to the iridium-containing precursor and the reactant simultaneously, where the substrate 210 is exposed to the iridium-containing precursor and the reactant sequentially, and where the reactant is pulsed continuously, and the iridium-containing precursor is pulsed intermittently, independently defines a process cycle. In some embodiments, the iridium-containing film 300 is deposited in a single process cycle. In some embodiments, the iridium-containing film 300 is deposited in a range of from 1 to 200 process cycles.

In one or more embodiments where the reactant is pulsed continuously, and the iridium-containing precursor is pulsed intermittently, the iridium-containing precursor is pulsed for a time period in a range of from 0.1 seconds to 10 seconds. In one or more embodiments where the reactant is pulsed continuously, and the iridium-containing precursor is pulsed intermittently, there is a time delay after each pulse of the iridium-containing precursor. In one or more embodiments where the reactant is pulsed continuously, and the iridium-containing precursor is pulsed intermittently, the time delay is in a range of from 0.1 seconds to 20 seconds. In one or more embodiments where the reactant is pulsed continuously, and the iridium-containing precursor is pulsed intermittently, the time delay is 15 seconds.

In one or more embodiments where the reactant is pulsed continuously, and the iridium-containing precursor is pulsed intermittently, the iridium-containing precursor is pulsed for a time period in a range of from 0.1 seconds to 10 seconds, followed by a time delay of 15 seconds where the reactant is pulsed continuously to define a process sequence. This process sequence can be repeated any suitable number of times to deposit the iridium-containing film 300 to a predetermined thickness.

In some embodiments, the iridium-containing film 300 comprises in a range of from 20 atomic percent iridium to 100 atomic percent iridium. In some embodiments, the iridium-containing film 300 comprises in a range of from 50 atomic percent iridium to 100 atomic percent iridium.

In some embodiments, the iridium-containing film 300 contains essentially no halogen atoms. As used in this manner, the term “contains essentially no halogen atoms” means the iridium-containing film 300 comprises less than or equal to about 2%, 1% or 0.5% of halogen atoms on an atomic basis. In some embodiments, the iridium-containing film 300 is free of halogen atoms.

Embodiments of the disclosure advantageously provide iridium-containing films, e.g., the iridium-containing film 300, having a resistivity of less than or equal to 300 μΩ·cm. In some embodiments, the iridium-containing film 300 has a resistivity of less than or equal to 200 μΩ·cm.

The iridium-containing film 300 may have any suitable thickness. In one or more embodiments, the iridium-containing film 300 has a thickness in a range of from about 2 Å to about 500 Å on the gapfill material 280 of the first feature 243 and the gapfill material 280 of the second feature 246. In one or more embodiments, the iridium-containing film 300 has a thickness in a range of from about 2 Å to about 500 Å on the gapfill material 280 of the first feature 243 and the gapfill material 280 of the second feature 246 and the metal liner 225. In one or more embodiments, the iridium-containing film 300 has a thickness in a range of from about 2 Å to about 500 Å on the gapfill material 280 of the first feature 243 and the gapfill material 280 of the second feature 246, the metal liner 225, and/or the barrier layer 220. In one or more embodiments, the iridium-containing film 300 is continuous at about 10 Å.

Advantageously, in one or more embodiments, the iridium-containing film 300 has a thickness of 20 Å on the gapfill material 280 of the first feature 243 and the gapfill material 280 of the second feature 246 and a thickness of 0 Å on the dielectric layer 245.

The selective deposition process of operation 180 can be performed at any suitable processing conditions. In some embodiments, the selective deposition process of operation 180 is performed at a pressure in a range of from 100 mTorr to 760 Torr. In some embodiments, the selective deposition process of operation 180 is performed at a temperature in a range of from 20° C. to 550° C.

The reactant according to one or more embodiments is a thermal reactant (e.g., without the use of plasma) or a plasma of the reactant. In embodiments where the reactant comprises a plasma of the reactant, the plasma may be generated by any suitable plasma source. The plasma may include, but is not limited to, one or more of an inductively coupled plasma (ICP) source, a capacitively coupled plasma (CCP) source, a microwave source, or a remote plasma source.

In some embodiments, the selective deposition process of operation 180 comprises a thermal atomic layer deposition (ALD) process performed at a temperature in the range of from 20° C. to 450° C.

In one or more embodiments, as shown in FIG. 3D, the iridium-containing film 300 is shown as selectively deposited on the gapfill material 280 of the first feature 243 and the gapfill material 280 of the second feature 246, the metal liner 225, and/or the barrier layer 220 in the top interconnect structure 202 relative to the dielectric layer 245, and an etch stop layer 242 is formed on top of the iridium-containing film 300 on the top interconnect structure 202, such that additional interconnect structures may be formed on top of the top interconnect structure 202.

In one or more embodiments, the substrate 210 is treated in accordance with operation 110 before after filling the gap with the gapfill material 280 at operation 170, prior to selectively depositing the iridium-containing film at operation 180.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films.

In some embodiments, the optional post-processing operation can be a process that modifies a property of the deposited film/layer. In some embodiments, the optional post-processing operation comprises annealing the substrate 210. In some embodiments, the annealing process is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate 210 increases the density, decreases the resistivity, and/or increases the purity of the layers, such as the iridium-containing film 300.

The methods described herein can be performed in any suitable processing system. Additional embodiments are directed to a cluster tool used to manufacture the microelectronic devices described herein and perform the methods described herein.

Another aspect of the disclosure pertains to a non-transitory computer readable medium including instructions, that, when executed by a controller of a processing system, causes the processing system to perform one or more operations of the methods described herein.

The disclosure is now described with reference to the following Examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1

An iridium-containing film was deposited on various substrate materials in accordance with the methods and processes described herein. The thickness of the iridium-containing film on each of the various substrate materials was measured.

TABLE 1
Thickness Of Iridium-Containing Film
On Various Substrate Materials

| | Approximate Thickness |
|---|---|
| Substrate | of Iridium-Containing |
| Material | Film (Å) |
| Silicon (Si) | 10 |
| Silicon Oxide (SiO₂) | 0 |
| Silicon Oxycarbide | 0 |
| (SiOC) | |
| Tantalum Nitride (TaN) | 10 |
| Ruthenium (Ru) | 20 |
| Tungsten (W) | 20 |
| Copper (Cu) | 30 |

Advantageously, the iridium-containing film deposited in accordance with the methods and processes described herein demonstrated inherent selectivity by selectively forming on the metallic material, e.g., ruthenium (Ru), tungsten (W), and copper (Cu), relative to the dielectric material, e.g., silicon oxide (SiO₂) and silicon oxycarbide (SiOC).

### Example 2

The iridium-containing film was deposited on a substrate comprising a metallic material (i.e., copper (Cu)) and a dielectric material (i.e., silicon oxide (SiO₂)) in accordance with the methods and processes described herein until the iridium-containing film reached a predetermined thickness of 250 Å on the metallic material. In a plurality of experiments, when the iridium-containing film was deposited until the iridium-containing film reached a predetermined thickness of 250 Å on the metallic material, the average thickness of the iridium-containing film on the dielectric material was in a range of from 10 Å to 40 Å.

Advantageously, the iridium-containing film deposited in accordance with the methods and processes described herein demonstrated inherent selectivity by selectively forming on the metallic material (i.e., copper (Cu)), relative to the dielectric material, e.g., silicon oxide (SiO₂) at a significantly greater thickness.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of selectively depositing an iridium-containing film, the method comprising:
exposing a substrate including a metallic material and a dielectric material to an iridium-containing precursor and a reactant to form the iridium-containing film, wherein the iridium-containing film selectively grows on the metallic material relative to the dielectric material.

2. The method of claim 1, wherein the substrate is exposed to the iridium-containing precursor and the reactant simultaneously.

3. The method of claim 1, wherein the substrate is exposed to the iridium-containing precursor and the reactant sequentially.

4. The method of claim 1, wherein the reactant is pulsed continuously, and the iridium-containing precursor is pulsed intermittently.

5. The method of claim 1, wherein the iridium-containing precursor comprises one or more of Ir(acac)₃, Ir(CpMe)(COD), Ir(CpEt)(COD), or Ir(CO)₃(tBusCyp).

6. The method of claim 1, wherein the reactant comprises one or more of hydrogen (H₂), ammonia (NH₃), nitrogen (N₂), argon (Ar), or helium (He).

7. The method of claim 1, wherein the metallic material comprises one or more of copper (Cu), manganese (Mn), tungsten (W), ruthenium (Ru), or molybdenum (Mo).

8. The method of claim 1, wherein the dielectric material comprises one or more of an oxide, silicon oxycarbide (SiOC), silicon oxycarbonitride (SiOCN), a low-κ dielectric material, or a high-κ dielectric material.

9. The method of claim 1, further comprising treating the substrate prior to exposing the substrate to the iridium-containing precursor and the reactant.

10. The method of claim 9, wherein treating the substrate comprises exposing the substrate to thermal H₂, thermal H₂/Ar, or thermal H₂/N₂.

11. The method of claim 9, wherein treating the substrate comprises exposing the substrate to a plasma of H₂/Ar, a plasma of H₂, a plasma of NH₃, or a plasma of H₂/NH₃.

12. The method of claim 1, performed at a temperature in a range of from 20° C. to 550° C.

13. The method of claim 12, comprising a thermal atomic layer deposition (ALD) process performed at a temperature in the range of from 20° C. to 450° C.

14. The method of claim 1, performed at a pressure in a range of from 100 mTorr to 760 Torr.

15. A method of manufacturing an interconnect structure, the method comprising:
forming a dielectric layer on a substrate, the dielectric layer including at least one feature defining a gap having sidewalls comprising a dielectric material and a bottom comprising a metallic material;
selectively depositing a barrier layer on the dielectric material;
depositing a metal liner on the barrier layer;
filling the gap with a gapfill material comprising one or more of copper (Cu), manganese (Mn), tungsten (W), ruthenium (Ru), or molybdenum (Mo); and
selectively depositing an iridium-containing film on the gapfill material relative to the dielectric material.

16. The method of claim 15, wherein selectively depositing the iridium-containing film comprises exposing the substrate to an iridium-containing precursor and a reactant.

17. The method of claim 16, wherein selectively depositing the iridium-containing film comprises:
exposing the substrate to the iridium-containing precursor and the reactant simultaneously;
exposing the substrate to the iridium-containing precursor and the reactant sequentially; or
pulsing the reactant continuously, while pulsing the iridium-containing precursor intermittently.

18. The method of claim 15, further comprising treating the substrate after filling the gap with the gapfill material prior to selectively depositing the iridium-containing film.

19. The method of claim 15, further comprising forming a blocking layer on the bottom prior to selectively depositing the barrier layer on the sidewalls.

20. The method of claim 16, wherein the iridium-containing precursor comprises one or more of Ir(acac)₃, Ir(CpMe)(COD), Ir(CpEt)(COD), or Ir(CO)₃(tBusCyp), and the reactant comprises one or more of hydrogen (H₂), ammonia (NH₃), nitrogen (N₂), argon (Ar), or helium (He).
